(19) United States
(12) Patent Application Publication
(10) Pub. No.: US 2007/0258307 A1
(43) Pub. Date: Nov. 8, 2007

(54) MEMORY CIRCUIT AND METHOD FOR REFRESHING DYNAMIC MEMORY CELLS

(76) Inventors: Manfred Proell, Dorfen (DE); Stephan Schroeder, Munich (DE); Wolfgang Ruf, Friedberg (DE); Hermann Haas, Hoehenkirchen-Siegertsbrunn (DE)

Correspondence Address: PATTERSON & SHERIDAN, LLP;Gero McClellan / Infineon / Qimonda, 3040 POST OAK BLVD.,, SUITE 1500, HOUSTON, TX, 77056, US

(21) Appl. No.: 11/742,572

(22) Filed: Apr. 30, 2007

(30) Foreign Application Priority Data
Apr. 29, 2006 (DE) 102006020098.5-55

(51) Int. Cl. G11C 7/00

(52) U.S. Cl. 365/222

(57) ABSTRACT

A memory circuit comprises a memory cell array with dynamic memory cells arranged on word lines and bit lines, a selection unit providing selection information and a refresh circuit selecting the memory cells in each case in dependence on the selection information and refreshing the selected memory cells so that any information stored therein is retained in each case.

### CROSS-REFERENCE TO RELATED APPLICATIONS

This application claims foreign priority benefits under 35 U.S.C. § 119 to co-pending German patent application number DE 10 2006 020 098.5-55, filed 29 Apr. 2006. This related patent application is herein incorporated by reference in its entirety.

### BACKGROUND OF THE INVENTION

A memory cell array of a DRAM memory circuit has word lines and bit lines. In the case of a memory access, first one of the word lines is activated and, as a result, the memory cells arranged on the word line are in each case conductively connected to an associated bit line. During this process, a charge flows from a memory cell capacitance of the memory cell into the bit line. This leads to a deflection of the bit line voltage which can be detected with the aid of a read amplifier.

The memory cell capacitance of a dynamic memory chip is usually formed by means of a memory capacitor which is arranged in the substrate of the memory chip. However, a charge stored in the memory capacitor weakens with time since charges leak off into the surrounding substrate. This can lead to a loss of data in the memory cell. To be able to read out the memory cell with the correct data content, the charge must not drop below a residual charge in the memory cell. The leaking off of the memory cell charge is compensated for by refreshing the memory cell within a defined period of time, i.e. recharging it with the corresponding charge so that an adequate residual charge is permanently present in the memory cell.

Apart from other operating modes, a memory chip can also be operated in a self-refreshing mode in which the memory chip itself arranges for the memory cells to be refreshed. This does not require any commands or addresses to be applied to the memory chip from the outside. Maintaining the charges in the memory capacitances is ensured by internally generated refresh commands, the time intervals between the refresh commands being defined in such a manner that an adequate residual charge is permanently present in the memory cells which leads to a correct reading-out of the content of the memory cell. The interval between the refresh events for refreshing a memory cell significantly determines the current consumption in the self-refresh mode. If the time intervals between the refresh events are short, the risk of a loss of data in the memory cells drops but the current consumption rises. If the intervals between the refresh events are extended for reducing the current consumption, there is a risk of reducing the stored charge below a minimum charge so that a loss of data may occur.

Therefore, a memory circuit should be provided, the current consumption of which is reduced in the self-refresh mode. Further, a method for refreshing memory cells should be provided in which the current consumption is minimized.

### SUMMARY OF THE INVENTION

A memory circuit is provided which comprises a memory cell array with dynamic memory cells arranged on word lines and bit lines, a selection unit for providing selection information and a refresh circuit for selecting the memory cells in each case in dependence on the selection information and refreshing or not refreshing the selected memory cells so that a respective information item stored therein is maintained.

The memory circuit makes it possible to refresh only those memory cells which are determined by the selection information. Due to the selection information, the refreshing can thus be restricted to the relevant memory cells, e.g. to the memory cells which have previously actually been written to by an application. This can lead to considerable current saving since memory applications frequently only access parts of the memory cell array so that only some of the memory cells need to be refreshed. Since the refreshing of the contents of the memory cells requires a certain current, current can be correspondingly saved by avoiding refreshing memory areas.

A method for refreshing dynamic memory cells in a memory cell array is provided, wherein the memory cells are arranged on word lines and bit lines. The method comprises the steps of providing selection information, selecting memory cells in dependence on the selection information and refreshing the selected memory cells in dependence on the selection information.

The selection unit can have a status memory for storing the selection information. In particular, the selection unit can also have a programming circuit configured to write a first status to the status memory in dependence on a write command on an address of the memory cell array in such a manner that the refresh circuit during a subsequent refresh refreshes the memory cells at the address. The programming circuit may be further configured to write a second status to the status memory in dependence on an enable signal with respect to an address of the memory cell array in such a manner that the refresh circuit suppresses the refreshing of the memory cells at the address during a subsequent refresh. In this manner, a memory area used once can also be enabled again during the operation of the memory circuit so that the information contained therein is discarded by not performing any further refreshing of the relevant memory cells.

Furthermore, a word line decoder can be provided for selecting one of the word lines for activation in dependence on an address information item, the refresh circuit having an address generator which successively provides an address information item for addressing each one of the word lines.

The refresh circuit can also have selection switches which are in each case arranged between the word line decoder and each one of the word lines in order to allow or to prevent an activation of the corresponding word line by the refresh circuit in dependence on the selection information provided by the selection unit.

Further selection switches can be provided which are arranged in parallel with the selection switches, the refresh circuit being arranged for opening the further selection switches in a refresh mode and closing them in a normal operating mode.

In one embodiment, the status memory may have status memory elements which are in each case allocated to one of the word lines, each of the selection switches being connected to an associated status memory element so that the switching state of each of the selection switches depends on a data item stored in the status memory element.

In particular, each of the status memory elements can have a programming circuit for placing the associated status memory element into a first state when writing to a memory cell on one of the word lines and for placing the associated status memory element into a second state when the memory circuit is switched on or an enable signal is provided. For memory elements in the first state, the associated selection switches are closed, and for memory elements in the second state the associated selection switches are opened.

The status memory elements may be provided as dynamic memory cells along one or more bit lines in the memory cell array so that a status memory cell is arranged on each of the word lines and can be read out by activating the word line, wherein first read out amplifiers are provided which are in each case connected to at least one of the bit lines which are connected to the dynamic memory cells and wherein a second read out amplifier is provided which is connected to one of the several bit lines which are connected to the status memory cells, wherein the first and second read out amplifiers can be activated for refreshing, wherein the refresh circuit successively activates the read out amplifiers so that the state of the status memory cell on the activated word line can be detected by the second read out amplifier and the first read out amplifiers can be activated or deactivated in dependence on the state in the status memory cell for amplifying the charge on the associated bit line or the several associated bit lines.

A programming circuit can be provided for writing a first state of a refresh data item which specifies that refreshing is to take place, or a second state which specifies that no refreshing is to take place, to the status memory cells, wherein the first state corresponds to a potential level in the direction of which the status memory cells discharge due to leakage currents in the unaddressed state.

It can be provided that the status memory cell is formed by a number of dynamic memory cells in order to provide a greater charge for storing the first or second state in the status memory cell.

The word lines can be provided with a number of local word line drivers in order to activate in each case sections of the corresponding word line, wherein the word line drivers can be activated in dependence on the content of the status memory cell associated with the corresponding word line.

Each section of the respective word line can be associated with a corresponding status memory cell so that a word line can be refreshed section by section in dependence on the selection information.

The refresh circuit can also have a selection circuit for forwarding the address information to the word line decoder in dependence on the selection information provided by the selection unit. In particular, a number of word line decoders can be provided for a number of memory cell arrays, the selection unit being arranged for forwarding the address information to each of the word line decoders in dependence on the selection information provided by the selection unit.

### BRIEF DESCRIPTION OF THE DRAWINGS

The features of the embodiments will become clear from the following description, taking in conjunction with the accompanying drawings. It is to be noted, however, that the accompanying drawings illustrate only typical embodiments and are, therefore, not to be considered limiting of the scope of the invention. It may admit other equally effective embodiments.

FIG. 1 shows a diagrammatic representation of a memory circuit according to a first embodiment;

FIG. 2 shows a diagrammatic representation of a memory circuit according to a second embodiment;

FIG. 3 shows a diagrammatic representation of a memory circuit according to a third embodiment;

FIG. 4 shows an exemplary circuit of a status memory element for allowing or preventing the refreshing of a memory cell located on a word line, according to one embodiment;

FIG. 5 shows a section from a memory circuit, in which the status memory elements are arranged as part of the memory cell array, according to one embodiment;

FIG. 6 shows a diagrammatic representation of a memory circuit, wherein the status memory elements are also provided as part of the memory cell array, according to one embodiment;

FIG. 7 shows a section from a memory circuit, in which the status memory elements are arranged with two dynamic memory cells of the memory cell array, according to one embodiment;

FIG. 8 shows a representation of a word line subdivided by local word line drivers, which can be optionally activated, according to one embodiment; and

FIG. 9 shows a representation, in which the local word line drivers can be selected by, in each case, one status memory element, according to one embodiment.

### DETAILED DESCRIPTION OF THE PREFERRED EMBODIMENT

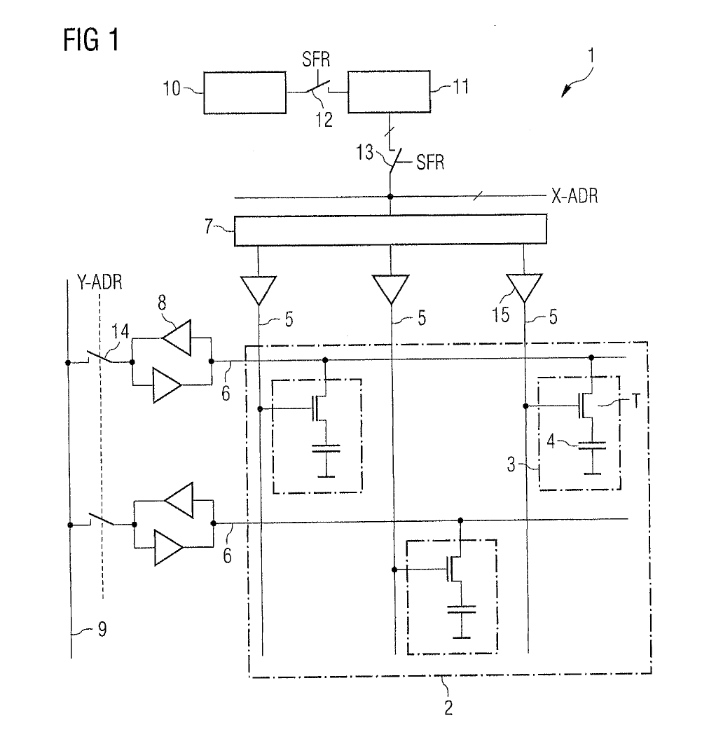

FIG. 1 shows a diagrammatic representation of a memory circuit 1 with a memory cell array 2. The memory cell array 2 comprises dynamic memory cells 3 in which an information item is in each case stored in the form of a charge in a capacitor 4. The memory cells 3 of the memory cell array 2 are arranged on word lines 5 and bit lines 6 so that, when one of the word lines 5 is activated, a corresponding selection transistor T of the memory cells 3 located on this word line is switched to conduct so that the charge flows to the corresponding bit line 6. The relevant word line 5 is selected by applying a word line address X-ADR to a word line decoder 7, which activates one of the word lines 5 in dependence on the word line address X-ADR via a corresponding word line driver 15 and leaves the other ones in the deactivated state. Each bit line 6 is connected to a read out amplifier 8 for amplifying the charge flowing from the addressed memory cell to the bit line 6 and outputting it to a data line 9. During writing, a corresponding signal is applied to the data line 9 and one of the read out amplifiers 8 connected to the bit lines 6 is selected via a corresponding switch 14 in dependence on a bit line address Y-ADR so that the corresponding data signal is applied as a charge to the corresponding bit line 6 so that the capacitor 4 of the addressed memory cell 3 is correspondingly charged up.

In the case of dynamic memory cells, the charge is stored in the capacitor 4. In the non-addressed state, however, the capacitor 4 loses its charge in the course of time so that, after some time, the information stored in the memory cell 3 cannot be read out correctly. For this reason, the memory cells are refreshed at regular intervals in familiar manner by successively addressing and activating the word lines 5 so that the charges of the memory cells located on the word line flow to the associated bit lines 6 and are there written back into the corresponding memory cells 3 by means of an amplification process with the aid of the read out amplifier 8 so that the information stored therein is refreshed and, as a result, is protected against loss of information.

The read out amplifiers 8 are usually connected, in each case, to two bit lines, only one memory cell 3 being provided per word line 5 for each of the bit line pairs. A charge in the capacitor 4 of the memory cell 3 is detected by carrying out a charge comparison on the bit lines 6 of the bit line pair with the aid of one of the read out amplifiers 8 since, after the corresponding word line 5 has been addressed on one of the two memory cells located on both bit lines 6 of the bit line pair, the charge of the relevant bit line changes with respect to the charge of the other bit line of the bit line pair.

In a self refresh mode, the memory circuit 1 automatically refreshes the memory cells 3. For this purpose, a refresh counter 10 is provided which generates a refresh address in a refresh address decoder 11 and applies it to the word line decoder 7. In the simplest case, the refresh address decoder 11 generates successive word line addresses X-ADR so that each of the word lines 5 is successively activated for a particular period of time, e.g. 40 ns, and is subsequently deactivated so that the charge of the corresponding memory cell 3 can flow to the bit line, can be amplified there by the read out amplifier 8 and, as a result, due to the selection transistor T completely switched to conduct, the corresponding charge is written back to the capacitors 4 of the relevant memory cells. Following this, the word lines are deactivated again and the bit lines are brought to a common equalizing potential. Following this, the refresh counter 10 is incremented so that a further refresh address is generated in the refresh address decoder 11. If the refresh address decoder reaches the highest possible word line address X-ADR, the next refresh on the word line is carried out with the lowest X address. The self refresh mode is determined by an external self refresh signal SFR with which a first switch 12 and a second switch 13 are driven. With an active self refresh signal SFR, the refresh counter 10 is connected to the refresh address decoder 11 and the latter is connected to the word line decoder 7.

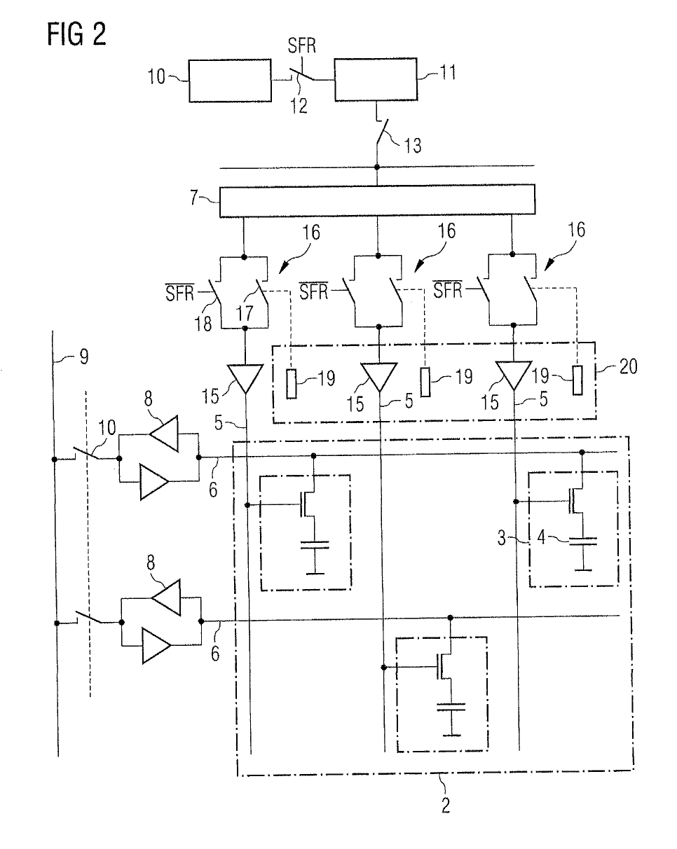

FIG. 2 shows a further memory circuit. Identical reference symbols correspond to elements of identical or similar function in the subsequent figures. In the embodiment shown, a switching device 16 which has a selection switch 17 and a mode switch 18 is provided between the word line decoder 7 and the respective word line driver 15. The selection switch 17 and the mode switch 18 are in each case connected in parallel with one another. The mode switch 18 is closed when the memory circuit 1 is not in the self refresh mode which is specified by the self refresh signal SFR. For example the word line decoder 7 is connected to the corresponding word lines via the word line drivers 15 when the memory circuit is in a normal operating mode. The selection switches 17 are driven by respective status memory elements 19 which either close or open the corresponding selection switch 17 in dependence on their state. For example, a logical “0” in the status memory element 19 specifies that the selection switch 17 is opened and a logical “1” specifies that the associated selection switch 17 is closed. With a logical “1”, the word line decoder 7 can activate the corresponding word line 5 in the self refresh mode in order to refresh the memory cells located on it. With a logical “0”, such activation of the word line 5 is prevented during the self refresh mode since both the mode switch 18 and the refresh switch 17 of the corresponding word line 5 are opened.

If the word lines 5 are not activated at regular intervals in order to refresh the memory cells located on them, the capacitors 4 of the memory cells 3 lose their charge so that any information stored therein is lost. The status memory elements 19 are part of a status memory 20 wherein, when the operating voltage is applied to the memory circuit, the status memory elements 19 are first loaded with a logical “0” which specifies that the refresh switches 17 are opened so that, when the memory circuit is in the self refresh mode, there can be no refreshing of the memory cells 3 by activating the word lines 5. It is only by writing to memory cells of the memory cell array 2 for the first time that individual word lines on which these memory cells are arranged are selected in that a logical “1” is written into the status memory element 19 associated with the corresponding word line so that the associated selection switch 17 is closed. As a result, the corresponding word line 5 can be activated for refreshing within a short time in the self refresh mode.

To save chip area, a status memory element 19 can be provided for a number of word lines, i.e. the status memory element 19 is used for opening and closing a number of refresh switches 17 for a corresponding number of word lines 5. If previously at least one of the memory cells of the corresponding word lines 5 was written to, a logical “1” is stored in the status memory element 19 associated with the word lines so that the corresponding word lines 5 are regularly refreshed in the self refresh mode. In addition, a status memory element 19 can select word lines of different memory cell arrays 2 (memory banks) so that these are noted for refreshing when there has been writing into a corresponding memory area of one of the memory cell arrays.

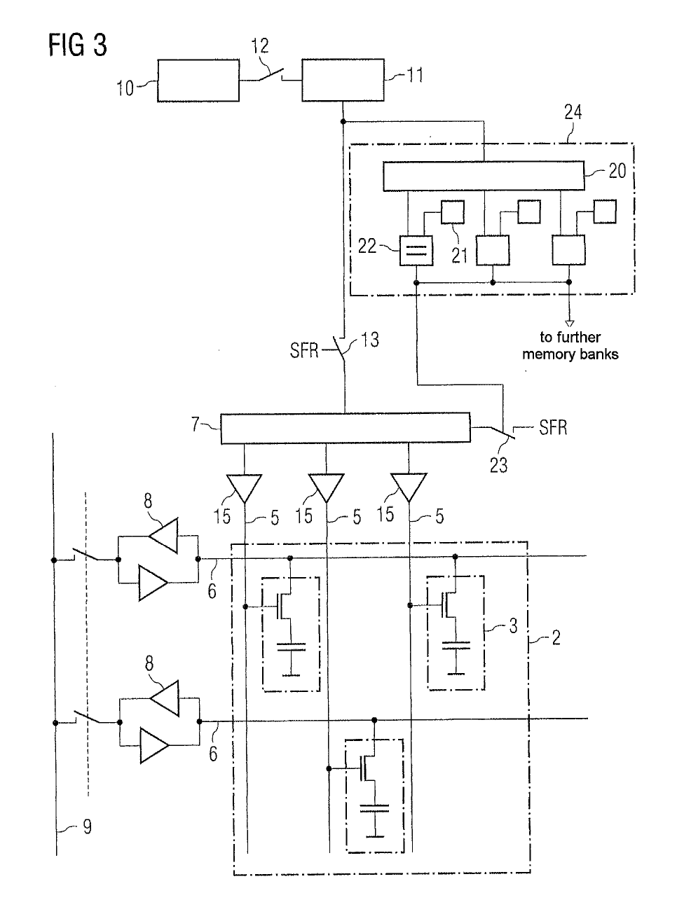

FIG. 3 shows a further memory circuit 2. Starting with the memory circuit as shown in FIG. 1, a further word line decoder 20 which decodes the refresh address supplied by the refresh address decoder 11 and in each case connects at a decoder output allocated to the refresh addresses to a first input of an AND gate 22, at the second inputs of which a respective status memory element 21 is connected, is provided in the embodiment of FIG. 3. As in the embodiment of FIG. 2, the status memory elements 21 specify which word lines 5 with the corresponding memory cells are to be activated and which are not. The outputs of the AND gates 22 are connected to one another so that the output signals output there are ORed with one another so that a logical “1” is present at a third switch 23 when the word line specified by the refresh address is to be activated, and that a logical “0” is output when the word line specified by the refresh address is not to be activated. In the case of a logical “0”, the third switch 23 remains open so that the self refresh signal is not present at the word line decoder 7 and the latter is thus deactivated. Providing the selection circuit 24 provided by the further word line decoder 20, the status memory elements 21 and the AND gates 22 for providing a selection signal for the third switch 23 is advantageous if a number of banks of memory cell arrays 2 are provided in the memory circuit 1 so that the selection circuit 24 can be used for simultaneously activating and deactivating a number of word line decoders 7 in order to perform the refreshing of memory cells by activating the relevant word line. As in the embodiment of FIG. 2, the status memory elements 21 can be reduced if a status memory element 21 is allocated to a number of word lines 5.

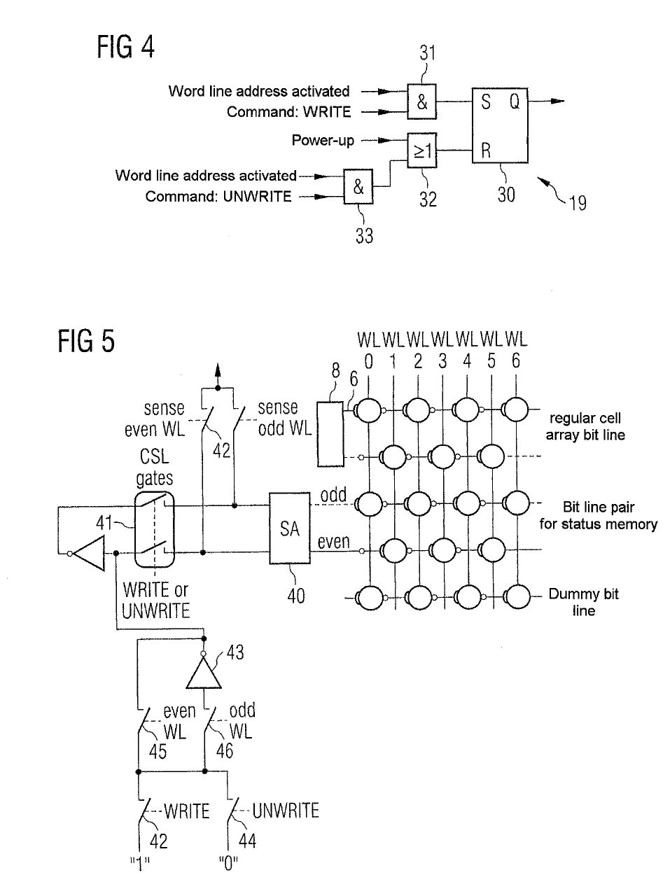

Referring to FIG. 4, the status memory elements 19, 21 as can be used in the embodiments of FIG. 2 and 3 and in the embodiments described in the text which follows are shown. FIG. 4 shows a status memory element 19 with an SR flip-flop 30 for storing the status signal. The set input S is connected to an output of a first AND gate 31. A first input of the first AND gate 31 is connected to one of the outputs for the word lines of the word line decoder 7 (embodiment of FIG. 2) and of the further word line decoder 20 (embodiment of FIG. 3) so that, when the word line allocated to the status memory element 19 is activated, a logical “1” is present at the first input of the first AND gate 31. A second input of the first AND gate 31 receives a write signal WRITE, applied internally or externally, which specifies that writing is to take place on the word line addressed by the word line address. This leads to a logical “1” being applied to the set input S of the flip-flop 30 so that the flip-flop 30 stores a logical “1” and outputs it at an output Q of the flip-flop 30. As described already previously with respect to FIGS. 2 and 3, a logical “1” stored in the status memory element 19, 21 has the effect that the word line 5 allocated to the status memory element 19, 21 is taken into consideration during a refresh so that the contents of the memory cells 3 connected to the word line are refreshed in the self refresh mode. A reset input R of the flip-flop 30 is connected to an output of an OR gate 32. At a first input of the OR gate 32, a switch-on signal POWERUP is applied which specifies with a logical “1” when the memory circuit is switched on and again assumes a logical “0” after a predetermined time interval. The switch-on signal results in a logical “1” at the output of the OR gate so that the flip-flop 30 is reset and a logical “0” is present at the output Q of the flip-flop 30. Since the circuit of the status memory elements shown is identical for all status memory elements 19, 21, a logical “0” is thus stored in all status memory elements 19, 21 after the memory circuit has been switched on.

A second input of the OR gate 32 is connected to an output of a second AND gate 33, at the first input of which the associated decoder output of the word line decoder 7 and of the further word line decoder 20, respectively, is applied. At a second input of the second AND gate 33, an enable signal or UNWRITE is applied which specifies that the memory cells arranged on the word line specified by the word line address hereafter no longer need to be taken into consideration during a refresh process since the data stored therein can be discarded. The release signal UNWRITE enables memory areas of the memory circuit needed once to be released, i.e. to be excepted from the subsequent refresh in order to reduce the current consumption for refreshing the released memory cells.

Where there is a number of banks of the memory circuit, the respective bank address must either be taken into consideration for distinguishing between the several banks during the activation of the corresponding word lines, or the corresponding word lines of all banks are activated in parallel by applying the word line address X-ADR so that during a subsequent write command WRITE or release signal UNWRITE, the state of the flip-flops 30 of all status memory elements 19, 21 allocated to the corresponding word lines is set.

If, as described before, a number of word lines are allocated to one status memory element, the status memory element 19, 21 is set, instead of by a specific word line address X-ADR by an arbitrary word line address X-ADR in the word line address area associated with the status memory element, in conjunction with the write command WRITE. For the implementation, further OR circuits are provided at the first inputs of the first and second AND gate 31, 33, at the respective inputs of which all corresponding decoder outputs of the word line address area of the word line decoder 7 and of the further word line decoder 20, respectively, are applied.

FIG. 5 shows a diagrammatic representation of a further memory circuit in which the status memory elements are arranged as part of the dynamic memory cells of the memory cell array. To simplify the representation, the memory cells are arranged as circles at the intersections of word lines 5 and bit lines 6. The read out amplifiers 8 are in each case connected to two mutually adjacent bit lines of a bit line pair in order to determine the content of a memory cell by detecting a charge difference on the bit lines 6 of the bit line pair after activation of one of the word lines 5. In this embodiment, the status memory elements are arranged not separately but as a part of the memory cell array 2. For this purpose, memory cells are preferably arranged at the edge of the memory cell array which are arranged between so-called dummy memory cells, which are necessary for reasons of the process, and the regular memory cells for storing the useful data. To provide a status memory element for each of the word lines, memory cells at a common bit line pair are adequate. The relevant bit line pair is connected to a further read out amplifier 40 which, after activation of one of the word lines 5, first reads out and evaluates the correspondingly activated status memory cell with the aid of the word line decoder. The read out amplifiers 8 and the further read out amplifier 40 can carry out an evaluation of the signals located on the bit lines after a short time. However, the main part of the current consumption relates to the cutting off of the charges on the bit lines 6 of the corresponding bit line pair to the full signal level. Depending on the value previously stored in the relevant status memory cell read out, the read out amplifiers 8 are now driven. The charges on the bit lines 6 of the bit line pair are spread by the respective read out amplifier 8 only if a corresponding information, e.g. a logical “1” is stored in the status memory cell, and not a logical “0” is stored. After the activation of the corresponding word line 5, this prevents current being consumed from the spreading of charges of memory cells located on the activated word line even though the information stored therein is not to be obtained since the memory cells on the relevant word line 5 have either not been used yet after the memory circuit has been switched on, or the information previously stored therein can be discarded.

Since the status memory cells on word lines with an even-numbered word line address are arranged on a first bit line of the bit line pair and status memory cells on word lines with an odd-numbered word line address are arranged on a second bit line of the bit line pair, either the data item from the first or second bit line of the bit line pair at which the status memory cells are arranged must be read out depending on via which one of the word lines, i.e. even- or odd-numbered, the status memory cell is read out. In the same manner, attention must be paid to the fact that the status memory cells are written to in dependence on the write command, the release signal UNWRITE and the word line address in the correct manner via the CSL switches 41 depending on word line address. To correctly output the content of the relevant addressed status memory cell, the outputs of the further read out amplifier 40 are connected to a demultiplexer 42 in order to output either the signal level of the first bit line or of the second bit line of the bit line pair at which the status memory cells are arranged and to provide it in a suitable manner to the read out amplifiers 8 so that these only perform a read out if, e.g. a logical “1” is applied.

The read out amplifiers 8 are slightly delayed, at least after the activation of the corresponding word line, so that first the relevant status memory cell can be evaluated by the further read out amplifier 40 and then the read out amplifiers 8 are activated or deactivated in dependence on the status memory value of the status memory cell. On activation of the read out amplifiers 8, a charge difference on the bit line pair connected to them is amplified and, as a result, the memory cell addressed by the activated word line is charged again, i.e. the charge of the capacitor of the memory cell is refreshed. If a logical “0” is read from the status memory cell and a corresponding control signal SS is applied to the read out amplifiers 8, the read out amplifiers 8 do not or do not completely evaluate the charge difference on the corresponding bit line pairs, thus saving the evaluation current. The potential difference of approx. 200 mV due to connecting the memory cells to the bit lines of the respective bit line pair are then equalized by an equalizing circuit (not shown) and, as a result, a medium potential is loaded into the relevant memory cells. If a word line is activated in normal operating mode, the corresponding status memory cell is also read out via the further read out amplifier 40. If then a write command WRITE is received (with the same bank address), a WRITE switch 42 is closed. Depending on whether an even- or odd-numbered word line is activated (indicated by a corresponding signal applied to the switches 45, 46), the write signal is inverted in the inverter 43 and the resultant signal is forwarded to the further read out amplifier 40 as a differential signal via the CSL switches 41. Only a release command UNWRITE, which leads to the provision of a logical “0” via a release switch 44, can lead to a logical “0” being stored in the relevant memory cell. For this purpose, the fact is also taken into consideration whether the status memory cell of the relevant word line is located on an even- or odd-numbered word line and the correct status is written into the status memory cell with the aid of the inverter 43.

Writing to and evaluating the status memory cells can also be carried out when the bit lines are twisted together. In this case, the circuit of the further read out amplifier 40 must be correspondingly adapted.

Since the status memory cells are not predefined after the memory circuit has been switched on, the reading out of the status memory cells can initially lead to arbitrary evaluation results. However, it is necessary to unambiguously predefine the status memory cells after the switch-on of the memory cells so that the status memory cells must first be written to with a logical “0”. This can be done, for example, by means of a suitable test mode in which all word lines are simultaneously activated and when all status memory cells can be simultaneously predefined with a corresponding release command UNWRITE. For this reason, it is appropriate to provide the user of the memory circuit with an additionally corresponding release command for completely releasing all memory cells, i.e. for setting all status memory cells to a state in which none of the word lines are refreshed in a self refresh mode. To distinguish a command for the complete release compared with a release command for an individual word line address, an arbitrary address bit of the bit line address transferred with the release command can be used.

Generally, dynamic memory cells have a preferred potential state which occurs when the memory cells have not been refreshed for a relatively long time or the leakage current is too high. A high potential level as a charge in the capacitors of the memory cell is usually the unstable potential state so that the memory cells typically discharge to a low potential state, i.e. to a physical “0”. First, a stored physical “1” was selected as status memory value for a word line already written, i.e. to be refreshed, and a physical “0” was selected as status memory value for a word line not to be refreshed. This initially arbitrary definition of the status memory values is justifiable as long as it is ensured that the status memory cells are tested for at least the same retention specification as the regular memory cells, i.e. can store the stored information without refreshing for at least as long as the regular memory cells. Otherwise, losing the charge of a status memory cell could lead to a change in the status memory value until the next refresh process. Such a change in status memory value takes place in a memory cell array of the above mentioned type typically from a physical “1” to a physical “0” which, with the present definition, would have the consequence of the status memory value of a used word line changing to the status memory value for an unused word line, i.e. a word line which is not to be refreshed. As a result, a necessary refreshing of one of the word lines could be suppressed and the data in all memory cells actually used for storing data on this word line could be destroyed. For this reason, extensive testing of the status memory cells is necessary for guaranteeing a reliable memory effect.

If the allocation is inverted, i.e. a physical “0” corresponds to a word line which is to be refreshed and a physical “1” corresponds to a word line in which no refreshing needs to take place, a poor retention time of a status memory cell is uncritical for the further operation in the self refresh mode. If the status memory cell is weak, i.e. it loses its stored charge very rapidly from a high charge potential to a low charge potential (from a physical “1” to a physical “0”), memory cells allocated to this actually unused word line are evaluated which results in a slight but unnecessary increase in current in the self refresh mode. Thus, a functional disturbance in the case of poor status memory cells, i.e. status memory cells with a short retention is prevented by a reduction in the current consumption in the self refresh mode which may be less optimized. It is possible to completely dispense with the testing of the status memory cells by a further test mode with such an allocation of the status signals.

In general, a first status of a status memory value which specifies that refreshing is to take place, and a second status of the refresh data item which specifies that no refreshing is to take place is defined in the status memory cells, wherein the first status corresponds to a potential level in the direction of which the status memory cell discharges due to leakage currents in the unaddressed state. If the charge in the status memory cells changes in the direction of a high charge potential, i.e. in the direction of a physical “1”, the physical “1” is correspondingly defined in such a manner that the corresponding word line is taken into consideration during refreshing and a physical “0” corresponds to a word line which is to remain unconsidered during refreshing.

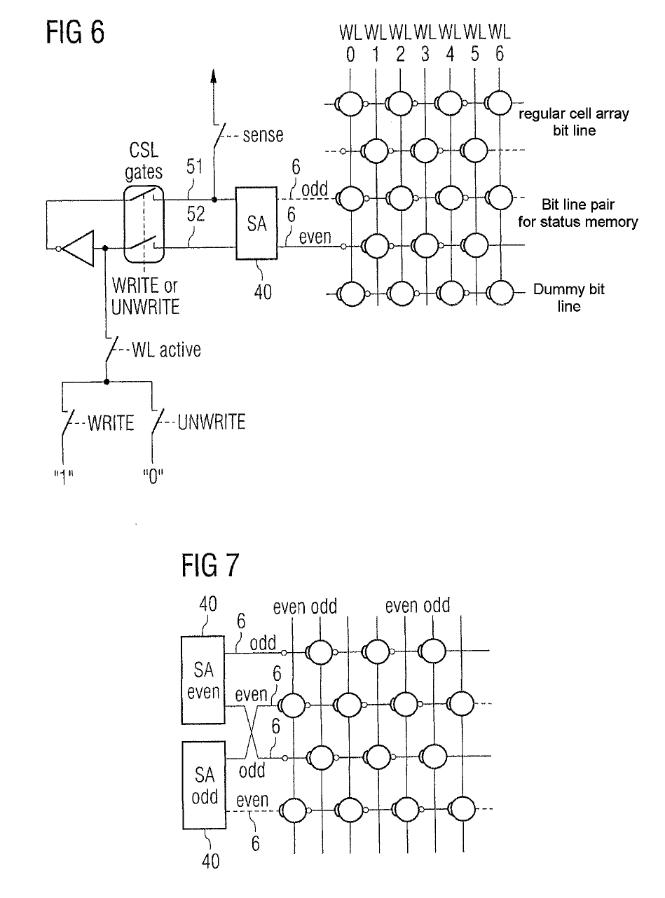

In the embodiment shown in FIG. 6, an alternative possibility is for arranging the memory circuit as shown. In this arrangement, the physical status memory values of the status memory cells are not permanently associated with the permission of a refresh or blocking of a refresh of the memory cells on the relevant word line. In the exemplary embodiment shown, a logical “0” allows the remaining bit lines to be evaluated by the read out amplifiers 8 as described before and a logical “1” prevents the charges on the bit line pairs to which the read out amplifiers 8 are connected from being evaluated or spread, respectively. A logical “0” can be read out of the corresponding status memory cells when either a low charge potential of the capacitors of the relevant memory cells on the first bit line 6_{ODD} or a high charge potential in the capacitors of the memory cells on the corresponding second bit line 6_{EVEN} of the bit line pair on which the status memory cells are arranged is stored. Since the further read out amplifier 40 outputs the charge difference, existing on the bit line pair, amplified to the two output lines 51 and 52, a state of a positive potential difference between the first and the second output line 51, 52 or of a negative potential difference between the two output lines can be defined. A positive potential difference means a high charge potential in the capacitor for the status memory cells on the first bit line 6_{ODD} and a low charge potential in the capacitor of the relevant status memory cell for the status memory cells on the second bit line 6_{EVEN}. This applies conversely to a negative potential difference on the output lines 51, 52. This allows the write circuit for writing to the status memory cells to be simplified somewhat.

FIG. 7 shows a section from a memory circuit according to a further embodiment of FIG. 6 in which only the status memory cells and corresponding further read out amplifiers 40 are shown. In this embodiment, the status memory value which specifies whether the relevant word line is to be refreshed or not is stored in two memory cells. Such a dual cell concept provides for the provision of a memory cell on both bit lines of a bit line pair and on a word line, which are charged oppositely to one another so that, depending on the information to be stored, a positive or a negative charge difference flows to the bit line of the bit line pair when the word line is activated. Such a dual cell concept is already known for regular memory cells and provides for increased evaluation reliability of the status memory cells in that two memory cells are available for storing the status memory value. So that the arrangement of the memory cells in the memory cell array is not changed for this purpose, two further read out amplifiers 40 are provided which are arranged at two adjacent bit line pairs, wherein the two first bit lines 6_{ODD} of the bit line pairs are connected to a first one of the further read out amplifiers 40 and the two second bit lines 6_{EVEN} of the two bit line pairs are connected to a second further read out amplifier 40, wherein two bit lines can be crossed over for connection to the corresponding read out amplifiers.

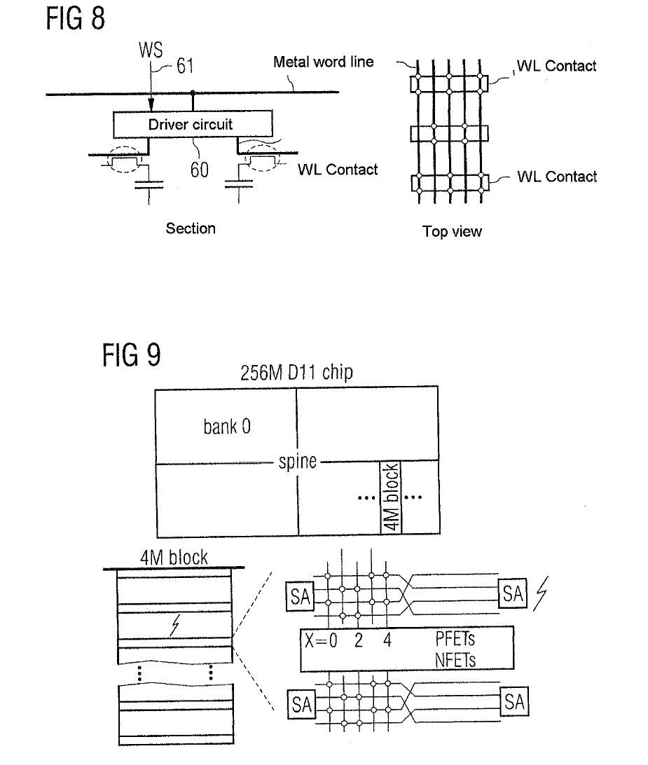

FIG. 8 shows a section from a memory circuit with a local word line driver 60 which separately drives word line sections of a word line 6. The local word line drivers 60 are usually provided for accelerating the activation of the word line, i.e. their recharging so that the charges can be read out more rapidly from the relevant memory cells. It can then be provided that the local word line drivers 60 are provided with a control connection 61 for receiving a control signal WS which specifies whether the local word line driver 60 is to be activated or not depending on the status memory value stored in the associated status memory cell. The operation of the local word line drivers can thus be suppressed already when the further read out amplifier 40 in the memory cell associated with the word line has detected that there is to be no refreshing. This makes it possible to prevent the storage capacitors from being connected to the relevant bit lines so that the current consumption can be lowered further due to the disconnected local word line drivers.

It can also be provided that in the case of a number of local word line drivers which subdivides a word line into a number of word line sections, separate status memory cells can be provided for each of the word line sections so that it is possible to define for each word line section whether refreshing is to take place or to be prevented. For this purpose, status memory cells are provided on a number of bit line pairs, the number of bit line pairs with status memory cells corresponding to the number of at least the word line sections which can be refreshed separately from one another. Naturally, it is also conceivable to provide a common status memory cell for a number of word line sections.

The above embodiments were described with reference to the exemplary embodiments with internally generated refresh signals. However, it is also possible to apply the concept to memory circuits in which refresh signals are applied externally to the memory circuit. The concepts for implementing a reduced current consumption in the memory circuit as described in the embodiments can also be combined with one another in order to obtain further embodiments.

The preceding description describes advantageous exemplary embodiments. The features disclosed therein and the claims and the drawings can, therefore, be useful for realizing various embodiments, both individually and in any combination. While the foregoing is directed to specific embodiments, other and further embodiments may be devised without departing from the basic scope, the scope being determined by the claims that follow.

What is claimed is:

1. A memory circuit, comprising:
a memory cell array with dynamic memory cells arranged at intersections of word lines and bit lines;
a selection unit providing selection information; and
a refresh circuit configured to select the memory cells according to the selection information, and further configured to refresh the selected memory cells so that any information stored therein is retained.

2. The memory circuit as claimed in claim 1, wherein the selection unit comprises a status memory storing the selection information.

3. The memory circuit as claimed in claim 2, wherein the selection unit further comprises a programming circuit configured to write a first status to the status memory in dependence on a write command with respect to a first address of the memory cell array so that the refresh circuit, during a subsequent refreshing, refreshes the memory cells at the address, the programming circuit writing a second state to the status memory in dependence on a release signal with respect to a second address of the memory cell array so that the refresh circuit suppresses the refreshing of the memory cells at the address during the subsequent refreshing.

4. The memory circuit as claimed in claim 2, wherein the refresh circuit comprises an address generator which successively provides an address information item addressing each of the word lines; and further comprising a word line decoder configured to select one of the word lines for activation in dependence on the respective generated address information items.

5. The memory circuit as claimed in claim 4, wherein the refresh circuit further comprises selection switches which are each respectively arranged between the word line decoder and each of the word lines, the respective selection switch selectively allowing and preventing an activation of the corresponding word line by the refresh circuit in dependence on the selection information provided by the selection unit.

6. The memory circuit as claimed in claim 5, further comprising additional selection switches arranged in parallel with the selection switches, the refresh circuit configured to open the additional selection switches in a refresh mode and close the additional selection switches in a normal operating mode.

7. The memory circuit as claimed in claim 5, wherein the status memory comprises a plurality of status memory elements which are each respectively allocated to one of the word lines, wherein each selection switch is connected to an associated status memory element so that the switching state of each selection switch depends on a data item stored in the respective status memory element.

8. The memory circuit as claimed in claim 7, wherein each status memory element comprises a programming circuit configured to place the associated status memory element into a first state when writing to a memory cell on one of the word lines, and place the associated status memory element into a second state when the memory circuit is at least one of switched on and provided with a release signal; wherein the selection switches are closed in a first state of the associated status memory element and are opened in a second state of the associated status memory element.

9. The memory circuit as claimed in claim 2, wherein the status memory elements are provided as additional dynamic memory cells along one or more additional bit lines in the memory cell array so that a status memory cell is arranged on each of the word lines and can be read out by activating the word line; and further comprising:
first read out amplifiers connected to at least one of the bit lines which are connected to the dynamic memory cells, and
a second read out amplifier connected to the one or more additional bit lines which are connected to the status memory cells, wherein the first and second read out amplifiers can be activated for refreshing;
wherein the refresh circuit successively activates the read out amplifiers in order to detect the state of the status memory cell on the activated word line by the second read out amplifier and in order to activate or deactivate the first read out amplifiers in dependence on the detected state in the status memory cell for amplifying the charge on the associated one or more bit lines.

10. The memory circuit as claimed in claim 9, further comprising a programming circuit configured to write, to the status memory cells, a first state of a refresh data item which specifies that refreshing is to take place, and a second state which specifies that no refreshing is to take place, wherein the first state corresponds to a potential level in the direction of which the status memory cells discharge due to leakage currents in the non-addressed state.

11. The memory circuit as claimed in claim 9, wherein a status memory cell is formed by a number of dynamic memory cells.

12. The memory circuit as claimed claim 9, further comprising a plurality of local word line drivers coupled to the word lines and configured to activate sections of a corresponding word line, wherein the word line drivers are activated in dependence on the content of the status memory cell allocated to the corresponding word line.

13. The memory circuit as claimed in claim 12, wherein a corresponding status memory cell is allocated to each section of the respective word line.

14. The memory circuit as claimed in claim 4, wherein the refresh circuit further comprises a selection circuit configured to forward the address information item to the word line decoder in dependence on the selection information provided by the selection unit.

15. The memory circuit as claimed in claim 14, further comprising a plurality of word line decoders for a plurality of memory cell arrays, wherein the selection unit forwards the address information item to each of the word line decoders in dependence on the selection information provided by the selection unit.

16. A method for refreshing dynamic memory cells in a memory cell array, wherein the memory cells are arranged at respective intersection of word lines and bit lines, the method comprising:
providing selection information;
selecting memory cells in the array on the basis of the selection information; and
refreshing the selected memory cells on the basis of the selection information.

17. The method as claimed in claim 16, wherein the selection information is stored in the array.

18. The method as claimed in claim 17, wherein one of the word lines is selected for activation on the basis of an address information item; and wherein an address information item is successively provided for addressing each of the word lines.

19. The method as claimed in claim 16, wherein activation of the corresponding word line is allowed or prevented on the basis of the selection information provided.

20. The method as claimed in claim 16, wherein the selection information is stored in a plurality of status memory elements which are each respectively allocated to one of the word lines, and further comprising:
placing a respective status memory element of a given word line into a first state when writing to a memory cell on the given word line, and placing respective status memory element into a second state when the memory circuit is at least one of switched on and provided with a release signal, wherein the given word line can be activated in the first state and cannot be activated in the second state.

21. The method as claimed in claim 18, wherein a given address information item is forwarded to a word line decoder depending on the selection information provided.

22. The method as claimed in claim 16, wherein the selection information is stored in a status memory cells of a status memory of the memory cell array so that a respective status memory cell is arranged on each of the word lines, wherein first read out amplifiers are each connected to at least one of the bit lines and wherein a second read out amplifier is connected to one or more additional bit lines which are connected to the status memory cells, and wherein the steps of providing, selecting and refreshing comprise:
successively activating the second read out amplifiers to detect the state of the status memory cell on the activated word line; and
selectively activating the first read out amplifiers depending on the detected state in the status memory cell.

23. A memory circuit, comprising:
a memory cell array with dynamic memory cells arranged on word lines and bit lines;
a selection unit configured to provide selection information; and
a refresh circuit configured to:
select the memory cells in each case in dependence on the selection information; and
refresh the selected memory cells so that any information stored therein is retained in each case;
wherein the selection unit comprises a programming circuit and a status memory, the status memory storing the selection information, the programming circuit configured to write a first status to the status memory in dependence on a write command to an address of the memory cell array so that the refresh circuit, during a subsequent refreshing, refreshes the memory cells at the address.

24. The memory circuit as claimed in claim 23, wherein the programming circuit writes a second state to the status memory in dependence on a release signal with respect to an address of the memory cell array so that the refresh circuit suppresses the refreshing of the memory cells at the address during a subsequent refreshing.

25. The memory circuit as claimed in claim 23, wherein the refresh circuit has an address generator which successively provides an address information item addressing each of the word lines and further comprising:
a word line decoder configured to select one of the word lines for activation in dependence on an address information item generated by the address generator.

26. The memory circuit as claimed in claim 23, wherein the refresh circuit further comprises a respective selection switch arranged between the word line decoder and each of the word lines, the respective selection switch configured to allow and prevent an activation of the corresponding word line by the refresh circuit in dependence on the selection information provided by the selection unit.

27. The memory circuit as claimed in claim 26, further comprising additional selection switches arranged in parallel with the selection switches, the refresh circuit configured to open the further selection switches in a refresh mode and close them in a normal operating mode.

28. The memory circuit as claimed in claim 26, wherein the status memory comprises status memory elements which are in each case allocated to one of the word lines, wherein each selection switch is connected to an associated status memory element so that the switching state of each selection switch depends on a data item stored in the status memory element.

29. The memory circuit as claimed in claim 23, wherein the status memory elements are additional dynamic memory cells disposed along one or more bit lines in the memory cell array so that a status memory cell is arranged on each of the word lines and can be read out by activating the word line, wherein first read out amplifiers are provided which are connected to at least one of the bit lines which are connected to the dynamic memory cells, and
wherein a second read out amplifier is provided which is connected to one or more bit lines which are connected to the status memory cells, wherein the first and second read out amplifiers are selectively activated for refreshing,
wherein the refresh circuit successively activates the read out amplifiers in order to detect the state of the status memory cell on the activated word line by the second read out amplifier and in order to activate or deactivate the first read out amplifiers in dependence on the state in the status memory cell for amplifying the charge on the associated one or more associated bit lines.

30. The memory circuit as claimed in claim 29, wherein the programming circuit is configured to write to the status memory cells a first state of a refresh data item which specifies that refreshing is to take place, and a second state which specifies that no refreshing is to take place, wherein the first state corresponds to a potential level in the direction of which the status memory cells discharge due to leakage currents in a non-addressed state.

31. The memory circuit as claimed in claim 29, wherein a status memory cell is formed by a plurality of dynamic memory cells.

32. The memory circuit as claimed claim 29, wherein the word lines are provided with a plurality of local word line drivers in order to activate in each case sections of the corresponding word line, wherein the word line drivers can be activated in dependence on the content of the status memory cell allocated to the corresponding word line.

33. The memory circuit as claimed in claim 23, wherein the refresh circuit further comprises a selection circuit, the selection circuit forwarding the address information to the word line decoder in dependence on the selection information provided by the selection unit.

34. The memory circuit as claimed in claim 33, wherein a plurality of word line decoders are provided for a plurality of memory cell arrays, wherein the selection unit forwards the address information to each of the word line decoders in dependence on the selection information provided by the selection unit.
